(19) United States
(12) Patent Application Publication
(10) Pub. No.: US 2012/0204924 A1
(43) Pub. Date: Aug. 16, 2012

(54) Photovoltaic module and method

(76) Inventors: Michael J. Nowlan, Arlington, MA (US); Robert D. Bradford, Mansfield, MA (US); Jason S. Chalfant, Billerica, MA (US)

(21) Appl. No.: 12/932,019

(22) Filed: Feb. 15, 2011

(51) Int. Cl. H01L 31/05; H01L 31/18; H01B 5/00

(52) U.S. Cl. 136/244; 174/70 C; 438/73; 438/57; 257/E31.001

(57) ABSTRACT

A photovoltaic module has solar cells electrically interconnected by string ribbons and bus ribbons adhered to a dielectric strip are located on both ends of the solar cell strings and are electrically connected to the string ribbons. The bus ribbon assembly includes a dielectric strip having a length for disposal coextensively with the photovoltaic module side and the bus ribbons are configured on the dielectric strip to register with corresponding string ribbons when the dielectric strip is disposed coextensively with the photovoltaic module.

### FIELD OF THE INVENTION

The subject invention relates to photovoltaic modules such as solar panels.

### BACKGROUND OF THE INVENTION

In a traditional solar panel, solar cells are electrically interconnected in strings using thin flat conductive interconnect “ribbons” or “tabs”. The solar cells may be crystalline silicon or thin film solar cells including amorphous silicon, CIGS, and CdTe. The ribbons are typically thin copper strands that may be coated with a tin or solder alloy such as tin-silver, tin-lead, tin-lead-silver, or bismuth-tin.

In one conventional design, the front of the first solar cell in a string is electrically connected to the back of the second solar cell in the string, the front of which is electrically connected to the back of the third solar cell, and so on using 2 or more spaced interconnect ribbons soldered to the cells. Strings of solar cells, in turn, are electrically connected by bus ribbons. A typical panel may also include a glass cover sheet and a weather protective back plastic sheet.

During manufacturing, a reel of copper bus ribbon typically 0.0254 cm thick and 0.508 cm wide is made available and a technician or automated system is instructed, for a specific panel, how long the bus ribbons are to be, how many bus ribbons are present on each side of the panel, and how they are arranged on each side of the panel. The copper bus ribbon may be coated with a tin or solder alloy such as tin-silver, tin-lead, tin-lead-silver, or bismuth-tin. The technician or automated system then cuts the copper stock material according to the instructions to produce the bus ribbons, arranges them, and solders the appropriate interconnect string ribbons to the appropriate bus ribbons. Sometimes, by-pass diodes are added between adjacent bus ribbons. The result can be numerous manufacturing steps.

Also, some modules such as c-Si photovoltaic modules are assembled by placing cell strings and bus ribbons on an encapsulant film resting on a glass sheet that forms the front (sun facing) surface of the module. Since the encapsulant has a low melting point (approximately 65° C. for ethylene vinyl acetate), a temporary thermal insulating layer must be placed between the bus ribbons and the encapsulant during ribbon soldering or welding to prevent the encapsulant from melting.

### BRIEF SUMMARY OF THE INVENTION

The invention provides, in one example, a bus ribbon assembly that increases throughput since only one part is dispensed, cut, and placed at the end of a module instead of three, four, or more individual bus ribbons. Aspects of the invention also eliminate the requirement of using a separate thermally insulating material between the bus ribbons and the encapsulant.

The subject invention results from the realization, in part, that in one preferred embodiment the throughput of photovoltaic module manufacturing is increased if a new bus ribbon assembly is used featuring multiple bus ribbons adhered to a dielectric strip in a fashion such that the bus ribbons are preregistered with a given photovoltaic panel design when the dielectric strip is cut to the length the same as or approximately the same as the width of the photovoltaic panel.

The subject invention, however, in other embodiments, need not achieve all these objectives and the claims hereof should not be limited to structures or methods capable of achieving these objectives.

The invention features a photovoltaic module comprising solar cells electrically interconnected by string ribbons forming strings of solar cells, a first set of bus ribbons having their bottom surfaces adhered to a dielectric strip and located on one end of the strings and electrically connected to the string ribbons, and a second set of bus ribbons having their bottom surfaces adhered to another dielectric strip located on an opposite end of the strings and electrically connected to the string ribbons.

Typically, the dielectric strips are made of material including polyester or polyamide and the bus ribbons are made of copper optionally with a tin or solder coating. The first set of bus ribbons may include spaced bus ribbons disposed on the dielectric strip arranged serially; the second set of bus ribbons may include spaced bus ribbons disposed on the dielectric strip arranged parallel to each other and also typically includes spaced bus ribbons arranged serially. In one design, the second set of bus ribbons include overlapping bus ribbons arranged serially and may further include a diode between adjacent overlapping bus ribbons. In one embodiment, a thermally insulative layer is included under the dielectric strip.

The invention also features a bus ribbon assembly for a photovoltaic module having a side length 1 where string ribbons are to be electrically interconnected. The bus ribbon assembly comprises a dielectric strip having a length 1 or approximately a length 1 for disposal coextensively with the photovoltaic module side of length 1 and bus ribbons having their bottom surfaces adhered to the dielectric strip to be electrically connected to the string ribbons. The bus ribbons are configured on the dielectric strip to register with corresponding string ribbons when the dielectric strip is disposed coextensively with the photovoltaic module.

The invention also features a method of manufacturing a photovoltaic module comprising electrically interconnecting solar cells using string ribbons forming strings of solar cells, adhering the bottom surfaces of a first set of bus ribbons to a first dielectric strip, coextensively placing the first dielectric strip on one end of the strings of solar cells, electrically connecting string ribbons to the first set of bus ribbons, adhering the bottom surfaces of a second set of bus ribbons to a second dielectric strip, coextensively placing the second dielectric strip on an opposite end of the strings of solar cells, and electrically connecting string ribbons to the second set of bus ribbons.

One method of manufacturing a photovoltaic module in accordance with an example of the invention includes determining the length of a photovoltaic module side where string ribbons are to be electrically interconnected with bus ribbons, forming a bus ribbon assembly by adhering on a portion of a dielectric strip of a length coextensive with the module bus ribbons arranged to register with corresponding string ribbons according to a predetermined registration scheme, providing a bus ribbon assembly during the manufacturing of the photovoltaic module, and electrically connecting string ribbons to corresponding bus ribbons of the bus ribbon assembly.

### BRIEF DESCRIPTION OF THE SEVERAL VIEWS OF THE DRAWINGS

Other objects, features and advantages will occur to those skilled in the art from the following description of a preferred embodiment and the accompanying drawings, in which:

FIG. 1 is a schematic partially cut-away view of an example of a photovoltaic module in accordance with the prior art showing both interconnect string ribbons and bus ribbons;

FIG. 2 is a schematic three-dimensional top view of one example of a portion of a bus ribbon assembly in accordance with the invention;

FIG. 3 is an exploded view showing one end of a photovoltaic module in accordance with another example of the invention;

FIG. 4 is a schematic exploded view showing an example of the power output side of the module shown in FIG. 3;

FIG. 5 is a schematic top view showing the assembly of FIG. 4 after lamination and also showing a junction box in accordance with an example of the invention;

FIG. 6 is a schematic exploded view showing an alternative design for the power output side of the module shown in FIG. 4; and

FIG. 7 is a schematic top view of the module shown in FIG. 6 after lamination and also showing a terminal box in accordance with an example of the invention.

### DETAILED DESCRIPTION OF THE INVENTION

Aside from the preferred embodiment or embodiments disclosed below, this invention is capable of other embodiments and of being practiced or being carried out in various ways. Thus, it is to be understood that the invention is not limited in its application to the details of construction and the arrangements of components set forth in the following description or illustrated in the drawings. If only one embodiment is described herein, the claims hereof are not to be limited to that embodiment. Moreover, the claims hereof are not to be read restrictively unless there is clear and convincing evidence manifesting a certain exclusion, restriction, or disclaimer.

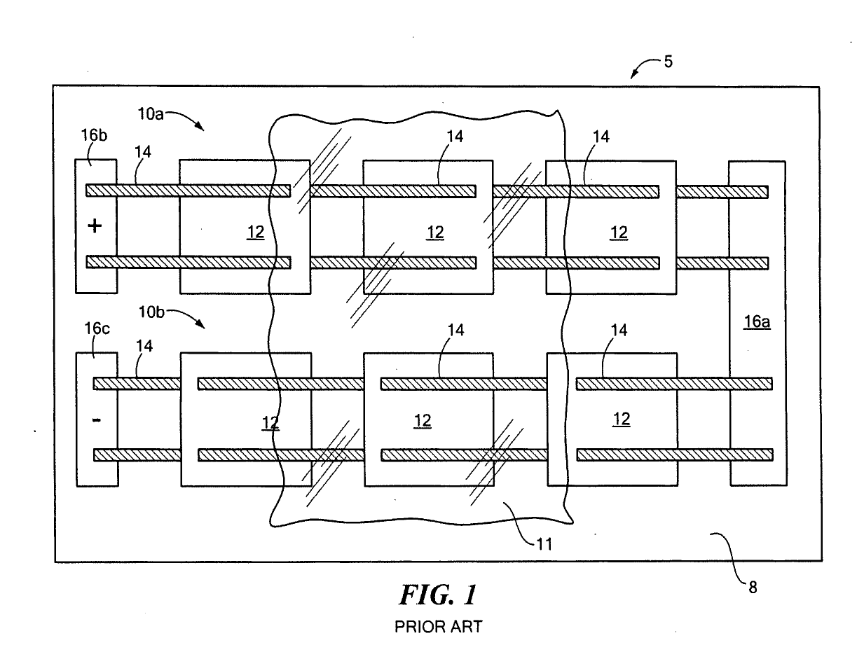

FIG. 1 shows a portion of photovoltaic panel 5 with back plastic layer 8, cell 12 strings 10a and 10b, and glass front layer 11. Each cell string in this simplistic example includes two interconnect string ribbons 14 which are connected to bus ribbon 16a on one side of the module and connected to bus ribbons 16b and 16c on the opposite end of the panel as shown. As discussed in the Background section above, the technician is instructed, for a specific panel design, how long bus ribbons 16a, 16b and 16c are to be, how many bus ribbons are present-on each side of the panel, and how they are arranged. The technician then cuts the ribbons, arranges them, and solders the appropriate interconnect string ribbons to the appropriate ribbon busses as shown. In the fairly simplistic design shown in FIG. 1, three bus ribbons must be cut and arranged as shown. Typically, in more complex design, numerous, for example, seven or more bus ribbons must be cut and arranged. Throughput of the manufacturing process can thus be fairly low.

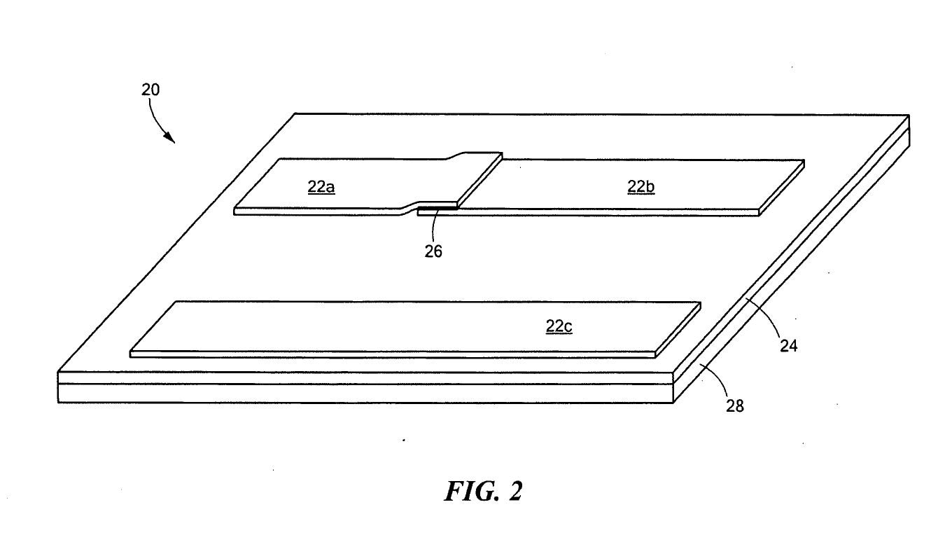

In one embodiment of the invention, bus ribbon assembly 20, a portion of which is shown in FIG. 2, includes bus ribbons 22a, 22b, and 22c with their bottom surfaces adhered (using an adhesive) to dielectric strip 24. Bus ribbon 22a and 22b are arranged serially and overlap in this example as shown with diode 26 (typically using surface mount technology) electrically interconnecting bus ribbons 22a and 22b. These bus ribbons, in turn, are arranged in parallel on strip 24 with bus ribbon 22c. This pattern may continue on dielectric strip 24. In any case, the bus ribbons are preferably prearranged on strip 24 to register with the interconnect string ribbons of a particular model of a photovoltaic module when dielectric strip 24 is cut and disposed adjacent to the photovoltaic module. In addition, strip 24 has a cut length such that it is the same as or approximately the same as the width of the photovoltaic panel so that when the strip is disposed on the panel, registration of the bus ribbons 22a, 22b, and 22c with the appropriate interconnect string ribbons is automatic. That is, the strip is coextensive with the panel and the bus ribbons on the strip are preregistered with their corresponding interconnect string ribbons.

The result is the ability to cut and assemble only one part instead of three or more individual bus ribbons. The dielectric strip used may even be selected to have the same color as the module backsheet (8, FIG. 1) (typically white or black) to hide the bus ribbons and improve module aesthetics. Thermally insulative layer 28 may also be provided under polyester (e.g., PET) or polyamide layer 24 enabling the soldering of the bus ribbons to their respective interconnect string ribbons without damaging any encapsulant associated with the assembly (typically between back sheet 8, FIG. 1 and cells 12 and/or between glass sheet 11 and cells 12).

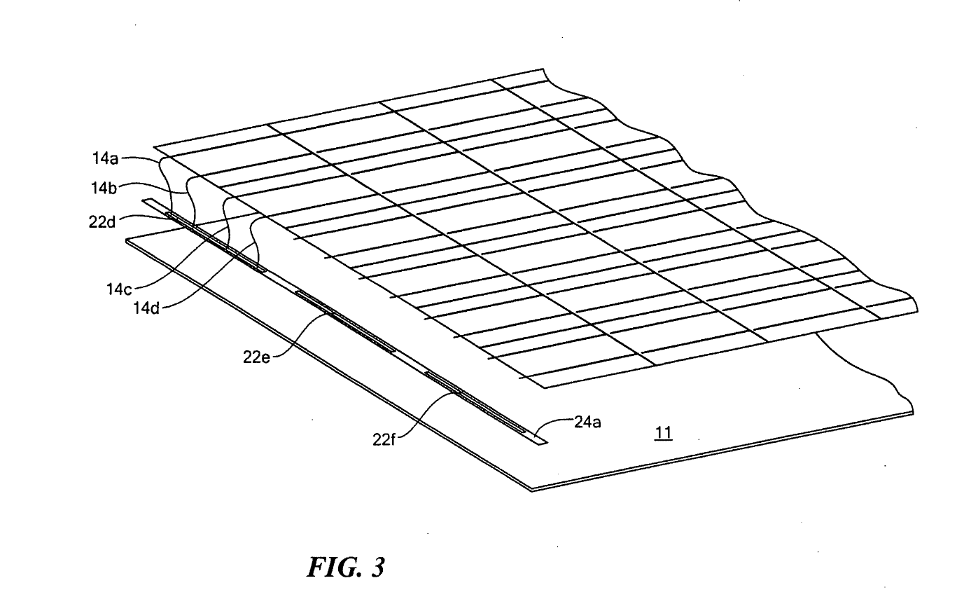

FIG. 3 shows one side of an example of a six string module with bus ribbons 22d, 22e, and 22f on dielectric strip 24a disposed above glass/encapsulant sheet 11 and having a length or cut to a length approximately the same as the width of glass/encapsulant sheet 11. In this way, it is self-evident how to align strip 24a in relation to the other panel components and, when so aligned, bus ribbons 22d, 22e, and 22f are preregistered with their corresponding interconnect string ribbons as shown. For example, interconnect string ribbons 14a, 14b, 14c and 14d will be electrically connected to bus ribbon 22d as shown.

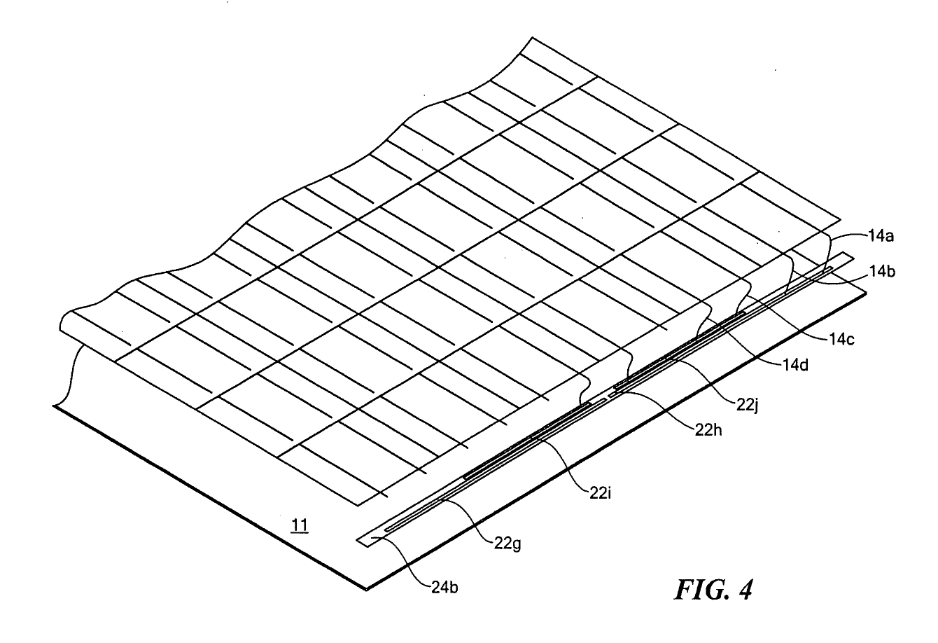

On the opposite end of the panel, FIG. 4 (the power output end) carrier strip 24b includes spaced bus ribbons 22g and 22h serially arranged and also spaced serially arranged bus ribbons 22i and 22j which are parallel to but spaced from bus ribbons 22g and 22h as shown. Here, interconnect string ribbons 14a and 14b are soldered to bus ribbon 22h but string ribbons 14c and 14d correspond to and are soldered to bus ribbon 22j. Again, dielectric strip 24b has a length commensurate with the length of the side of the panel glass and, when disposed as shown, results in automatic registration of the cell strings with their appropriate bus ribbons. The design of the panel will dictate the arrangement of the bus ribbons on the dielectric strip, their lengths, and which string ribbons correspond to which bus ribbons.

The dielectric strips can be made of polyester or a polyamide or other electrically insulating film, may include an adhesive for bonding the strip to the bus ribbons and/or to the insulating layer, if used, and/or to the encapsulant sheet, and are typically about 0.0051 cm thick and 0.7 to 1.3 cm wide. The bus ribbons are usually made of copper.

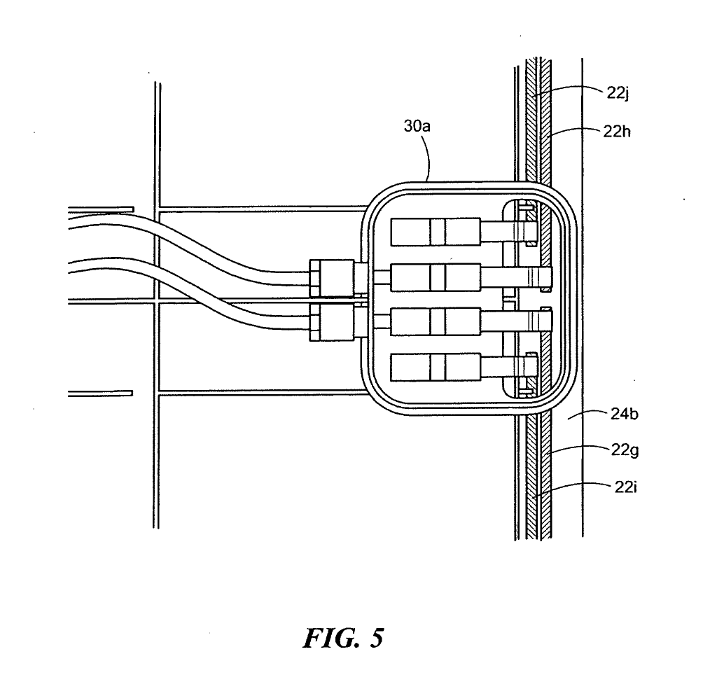

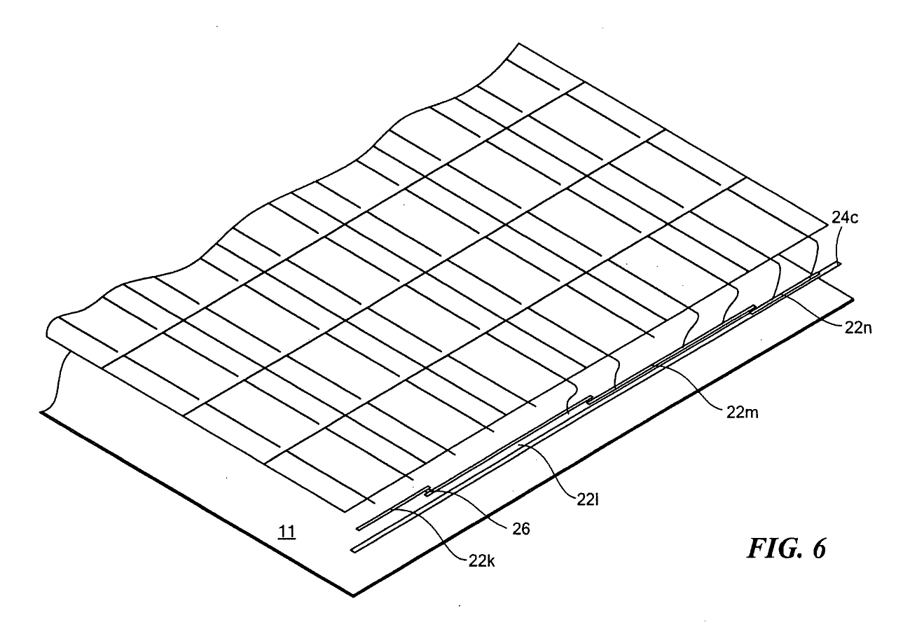

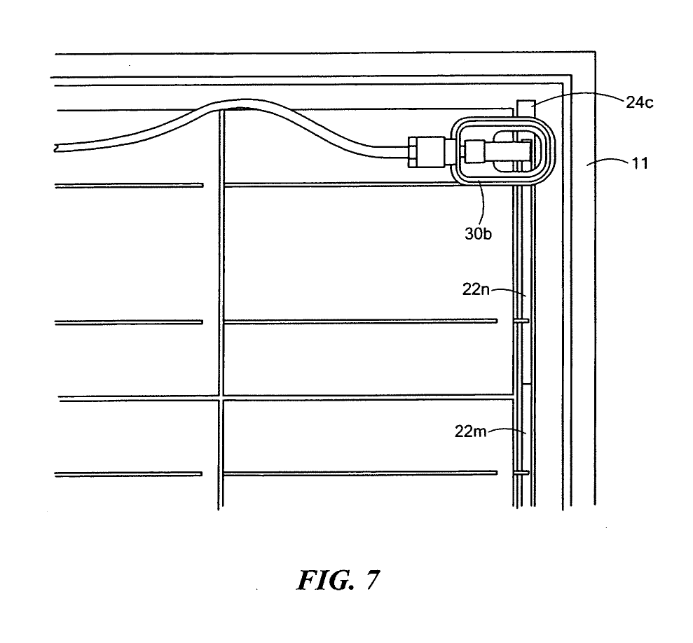

FIG. 5 shows junction box 30a for the design shown in FIG. 4 and the resulting neat look of the bus tape assembly after the string ribbons are connected to their respective bus ribbons and after lamination. The module backsheet and a cover for the junction box are not shown. FIG. 6 shows a design for the power output end where bus ribbons 22k, 22l, 22m and 22n on dielectric strip 24c are serially overlapping and there is a diode between each adjacent pair of bus ribbons. For example, as shown, diode chip 26 electrically interconnects bus ribbons 22k and 22l. FIG. 7 shows junction box 30b for this design and the resulting look of the bus strips after the string ribbons are connected to their respective bus ribbons and after module lamination.

In accordance with examples of the subject invention, multiple bus ribbons may be placed on the dielectric strip in the registration locations required for a specific panel design. Each assembly could be prefabricated either as a single assembly or as multiple assemblies on one continuous dielectric strip which is mounted on a reel for ease of handling, dispensing, and cutting. Preferably, these assemblies are constructed prior to module assembly and supplied in a bulk format. These prefabricated bus ribbon assemblies simplify the module bussing operations since only one part is dispensed, cut, and placed at each end of the module instead of three or more parts as was the case with the prior art. The result is increased throughput (modules per hour) of the bussing process and a process which allows for significant simplification of automated bussing equipment which reduces capital costs or results in a significant labor reduction for manual bussing operations. In FIG. 5, junction box 30a includes by-pass diodes. When diodes are included in the bus assembly as shown in FIG. 6, they are not needed in the junction box and a pair of much simpler, lower cost terminal boxes can be used as shown in FIG. 7. By using or adding a thermally insulative material to the bus tape assembly, the bus ribbons can be soldered or welded directly on the encapsulant layer of the module eliminating the need for placing or moving a temporary insulating layer and therefore again simplifying the bussing process.

In accordance with one method of the subject invention, manufacturing a photovoltaic module includes electrically interconnecting solar cells by string ribbons forming strings of solar cells. At some point, the bottom surfaces of a first set of spaced bus ribbons are adhered to a dielectric strip and the dielectric strip is placed on one end of the strings of solar cells. The string ribbons are electrically connected to the first set of bus ribbons. The same process is undertaken on the other side of the panel. The method may include determining the length of a photovoltaic module side where string ribbons are to be electrically interconnected, adhering on a portion of a dielectric strip of length 1 bus ribbons spaced to register with the string ribbons according to a predetermined registration scheme, and providing a dielectric strip of length 1 during the manufacturing of the photovoltaic module as shown in FIGS. 3 and 4.

Although specific features of the invention are shown in some drawings and not in others, this is for convenience only as each feature may be combined with any or all of the other features in accordance with the invention. The words “including”, “comprising”, “having”, and “with” as used herein are to be interpreted broadly and comprehensively and are not limited to any physical interconnection. Moreover, any embodiments disclosed in the subject application are not to be taken as the only possible embodiments.

In addition, any amendment presented during the prosecution of the patent application for this patent is not a disclaimer of any claim element presented in the application as filed: those skilled in the art cannot reasonably be expected to draft a claim that would literally encompass all possible equivalents, many equivalents will be unforeseeable at the time of the amendment and are beyond a fair interpretation of what is to be surrendered (if anything), the rationale underlying the amendment may bear no more than a tangential relation to many equivalents, and/or there are many other reasons the applicant can not be expected to describe certain insubstantial substitutes for any claim element amended.

Other embodiments will occur to those skilled in the art and are within the following claims.

What is claimed is:

1. A photovoltaic module comprising:
solar cells electrically interconnected by string ribbons forming strings of solar cells;
a first set of bus ribbons having their bottom surfaces adhered to a dielectric strip and located on one end of said strings and electrically connected to the string ribbons; and
a second set of bus ribbons having their bottom surfaces adhered to another dielectric strip located on an opposite end of said strings and electrically connected to the string ribbons.

2. The module of claim 1 in which the dielectric strips are made of material including polyester or polyamide.

3. The module of claim 1 in which the bus ribbons include copper.

4. The module of claim 1 in which the first set of bus ribbons include spaced bus ribbons disposed on the dielectric strip arranged serially.

5. The module of claim 1 in which the second set of bus ribbons include spaced bus ribbons disposed on the dielectric strip arranged parallel to each other.

6. The module of claim 5 in which the second set of bus ribbons further includes spaced bus ribbons arranged serially.

7. The module of claim 1 in which said second set of bus ribbons include overlapping bus ribbons arranged serially.

8. The module of claim 7 further including a diode between adjacent overlapping bus ribbons.

9. The module of claim 1 further including a thermally insulative layer under said dielectric strip.

10. A bus ribbon assembly for a photovoltaic module having a side of length 1 where string ribbons are to be electrically interconnected, the bus ribbon assembly comprising:
a dielectric strip having a length 1 or approximately a length 1 for disposal coextensively with said photovoltaic module side of length 1;
bus ribbons having their bottom surfaces adhered to said dielectric strip to be electrically connected to said string ribbons; and
said bus ribbons configured on said dielectric strip to register with corresponding string ribbons when said dielectric strip is disposed coextensively with said photovoltaic module.

11. The bus ribbon assembly of claim 10 in which the dielectric strip is made of electrically nonconductive material such as polyester or polyamide.

12. The bus ribbon assembly of claim 10 in which said bus ribbons include copper.

13. The bus ribbon assembly of claim 10 in which spaced bus ribbons are arranged serially on said dielectric strip.

14. The bus ribbon assembly of claim 10 in which the spaced ribbons are arranged parallel to each other on said dielectric strip.

15. The bus ribbon assembly of claim 10 in which some bus ribbons are arranged serially on said dielectric strip and some bus ribbons are arranged parallel to each other on said dielectric strip.

16. The bus ribbon assembly of claim 10 in which the bus ribbons include overlapping bus ribbons arranged serially on said dielectric strip.

17. The bus ribbon assembly of claim 16 further including a diode between overlapped bus ribbons.

18. The bus ribbon assembly of claim 10 further including a thermally insulative layer under said dielectric strip.

19. A method of manufacturing a photovoltaic module, the method comprising:
electrically interconnecting solar cells using string ribbons forming strings of solar cells;
adhering the bottom surfaces of a first set of bus ribbons to a first dielectric strip;
coextensively placing said first dielectric strip on one end of said strings of solar cells;
electrically connecting string ribbons to said first set of bus ribbons;
adhering the bottom surfaces of a second set of bus ribbons to a second dielectric strip;
coextensively placing said second dielectric strip on an opposite end of said strings of solar cells; and
electrically connecting string ribbons to said second set of bus ribbons.

20. A method of manufacturing a photovoltaic module, the method comprising:
determining the length of a photovoltaic module side where string ribbons are to be electrically interconnected with bus ribbons;
forming a bus ribbon assembly by adhering on a portion of a dielectric strip of a length coextensive with the module bus ribbons arranged to register with corresponding string ribbons according to a predetermined registration scheme;
providing a bus ribbon assembly of said determined length during the manufacturing of the photovoltaic module; and
electrically connecting string ribbons to corresponding bus ribbons of the bus ribbon assembly.
